(19) United States
(12) Patent Application Publication
(10) Pub. No.: US 2014/0290981 A1
(43) Pub. Date: Oct. 2, 2014

(54) PRINTED CIRCUIT BOARD

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: YU-HSU LIN, Santa Clara, CA (US); GUANG-FENG OU, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/106,902

(22) Filed: Dec. 16, 2013

(30) Foreign Application Priority Data
Apr. 1, 2013 (CN) 2013101095447

(51) Int. Cl. H05K 1/02

(52) U.S. Cl. CPC H05K 1/023
USPC 174/250

(57) ABSTRACT

A printed circuit board includes a board body, a signal transmission line laid in the board body, and a metal bracket attached to the board body. The metal bracket tightly abuts side surfaces of the board body and shields electromagnetic interference of the signal transmission line when the signal transmission line transmits high-speed differential signals.

### BACKGROUND

1. Technical Field

The present disclosure relates to a printed circuit board for eliminating electromagnetic interference (EMI).

2. Description of Related Art

Printed circuit boards are designed for coupling control chips to electronic devices. Signal transmission lines are laid on the PCB to transmit signals, such as high-speed differential signals. However, high-speed differential signals generate electromagnetic interference (EMI) and an edge effect in the signal transmission lines. Electromagnetic interference often causes digital system failures.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of a first embodiment of a printed circuit board (PCB).

FIG. 2 is an assembled view of the PCB of FIG. 1.

FIG. 3 is an isometric, exploded view of a second embodiment of a PCB.

FIG. 4 is an assembled view of the PCB of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

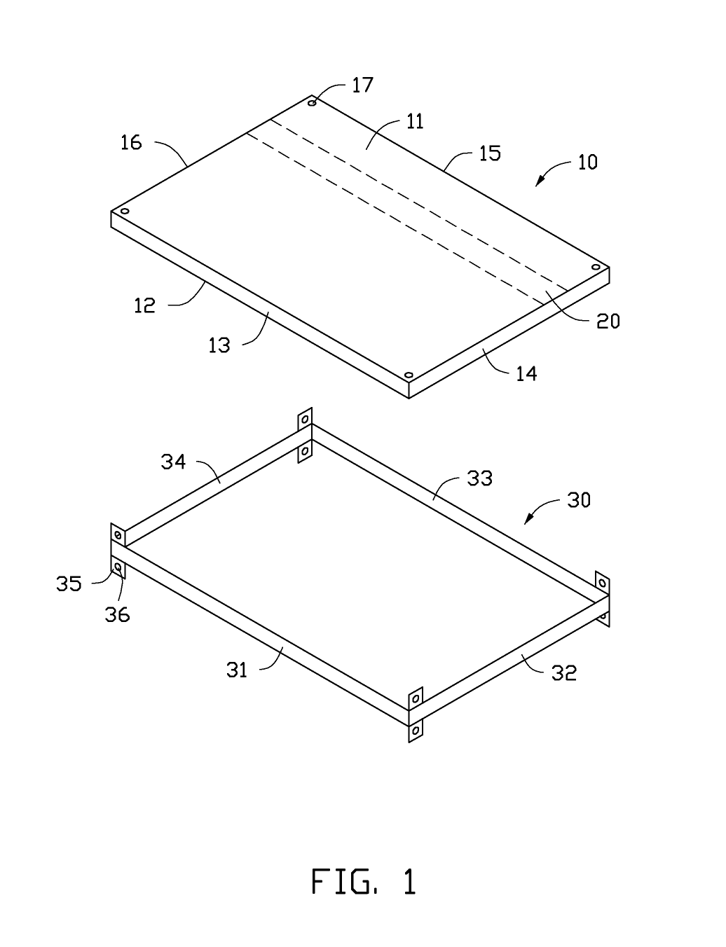

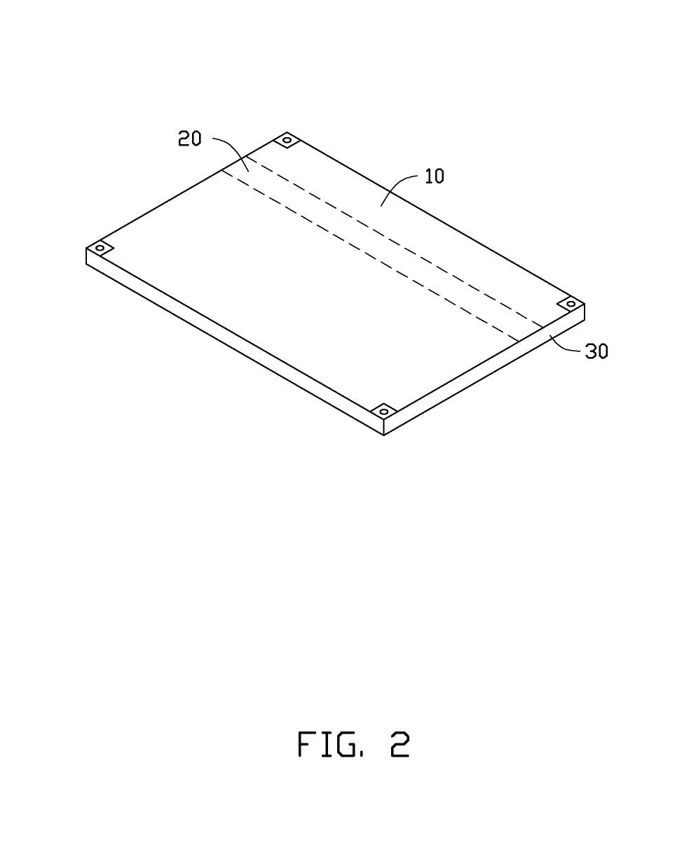

FIGS. 1 and 2 show a printed circuit board (PCB) in accordance with a first embodiment. The PCB includes a board body 10 having a top surface 11, a bottom surface 12, a first side surface 13, a second side surface 14, a third side surface 15, and a fourth side surface 16. A signal transmission line 20 is laid in the board body 10 adjacent to the third side surface 15. A through hole 17 is defined in each of four corners of the board body 10.

A metal bracket 30 is attached to the board body 10. The metal bracket 30 includes a first connecting portion 31, a second connecting portion 32, a third connecting portion 33, and a fourth connecting portion 34 which are serially connected. The first connecting portion 31, the second connecting portion 32, the third connecting portion 33, and the fourth connecting portion 34 tightly abut the first side surface 13, the second side surface 14, the third side surface 15, and the fourth side surface 16, respectively. A mounting portion 35 extends from each of an upper edge and a lower edge adjacent to an end of each of the first connecting portion 31, the second connecting portion 32, the third connecting portion 33, and the fourth connecting portion 34. A mounting hole 36 is defined in each of the mounting portions 35.

The mounting portions 35 are mounted to the top surface 11 and the bottom surface 12. A fastener (not shown) is received through a corresponding through hole 17 and a corresponding mounting hole 36 to fix the metal bracket 30 on the board body 10.

In one embodiment, the mounting portions 35 are substantially square. A diameter of a through hole 17 is substantially equal to a diameter of a corresponding mounting hole 36. A length of the first connecting portion 31 and a length of the third connecting portion 33 are substantially equal to a length of the board body 10. A length of the second connecting portion 32 and a length of the fourth connecting portion 34 are substantially equal to a width of the board body 10. A width of the first connecting portion 31, the second connecting portion 32, the third connecting portion 33, and the fourth connecting portion 34 are substantially equal to a thickness of the board body 10. In one embodiment, the metal bracket 30 is made of copper. In another embodiment, the metal bracket 30 is made of aluminum. As the metal bracket 30 is fixed to the board body 10, an electromagnetic interference (EMI) effect generated by the signal transmission line 20 is shielded by the first connecting portion 31, the second connecting portion 32, the third connecting portion 33, and the fourth connecting portion 34. An edge effect in the signal transmission line 20 is also eliminated.

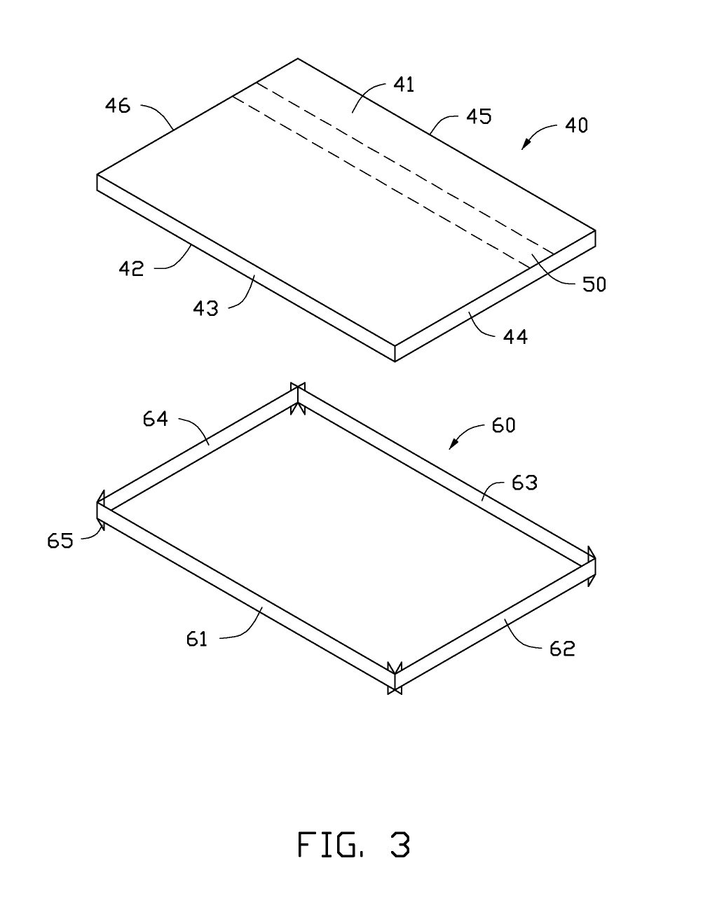

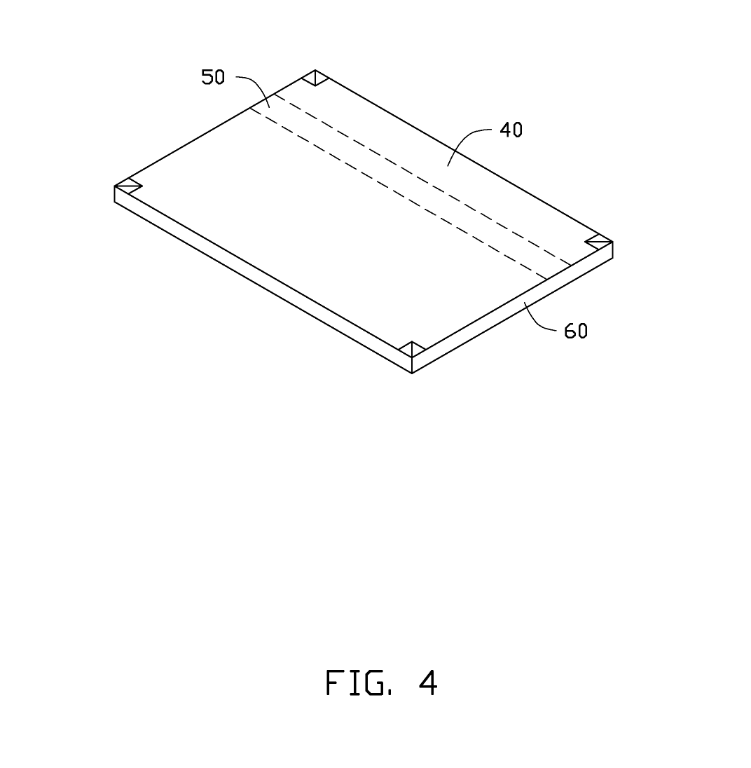

FIGS. 3 and 4 show a PCB in accordance with a second embodiment. The PCB includes a board body 40 having a top surface 41, a bottom surface 42, a first side surface 43, a second side surface 44, a third side surface 45, and a fourth side surface 46. A signal transmission line 50 is laid in the board body 40 adjacent to the third side surface 45.

A metal bracket 60 is attached to the board body 40. The metal bracket 60 includes a first connecting portion 61, a second connecting portion 62, a third connecting portion 63, and a fourth connecting portion 64 connected which are serially connected. The first connecting portion 61, the second connecting portion 62, the third connecting portion 63, and the fourth connecting portion 64 tightly abut the first side surface 43, the second side surface 44, the third side surface 45, and the fourth side surface 46, respectively. A mounting portion 65 extends from each of an upper edge and a lower edge adjacent to each of two ends of each of the first connecting portion 61, the second connecting portion 62, the third connecting portion 63, and the fourth connecting portion 64. In one embodiment, the mounting portions 65 are substantially triangle-shaped.

The mounting portions 65 are riveted to the top surface 41 and the bottom surface 42. A length of the first connecting portion 61 and a length of the third connecting portion 63 are substantially equal to a length of the board body 40. A length of the second connecting portion 62 and a length of the fourth connecting portion 64 are substantially equal to a width of the board body 40. A width of the first connecting portion 61, the second connecting portion 62, the third connecting portion 63, and the fourth connecting portion 64 are substantially equal to a thickness of the board body 40. In one embodiment, the metal bracket 60 is made of copper. In another embodiment, the metal bracket 60 is made of aluminum. As the metal bracket 60 is attached to the board body 40, an EMI effect generated by the signal transmission line 50 is shielded by the first connecting portion 61, the second connecting portion 62, the third connecting portion 63, and the fourth connecting portion 64. An edge effect in the signal transmission line 50 is also eliminated.

A software application called CST was used to simulate an EMI value of the PCB. For the simulated conditions, the length of each of the board bodies 10 and 40 is about 5000 milli-inches (mil), the width of each of the board bodies 10 and 40 is about 3000 mil, and the thickness of each of the board bodies 10 and 40 is about 54.2 mil. A distance between the signal transmission line 20 and the third side surface 15 is about 10 mil. A distance between the signal transmission line 50 and the third side surface 45 is about 10 mil. A length of each of the signal transmission lines 20 and 50 is about 4990 mil. A width of each of the signal transmission lines 20 and 50 is about 5 mil. The table below shows that according to the simulated conditions, when a frequency of high-speed differential signals transmitted in the signal transmission lines 20 and 50 increases from about 0.2 gigahertz (GHZ) to about 10 GHZ, the following EMI values (measured in volts per meter) are obtained:

| Frequency | EMI value of PCB without | EMI value of PCB with |
|---|---|---|
| (GHZ) | metal bracket (V/M) | metal bracket (V/M) |
| 0.2 | 0.00843 | 0.00511 |
| 0.4 | 0.0269 | 0.0161 |
| 0.6 | 0.0807 | 0.0474 |
| 0.8 | 0.114 | 0.0652 |
| 1 | 0.074 | 0.0418 |
| 2 | 0.168 | 0.0933 |
| 3 | 0.152 | 0.0928 |
| 4 | 0.229 | 0.148 |
| 5 | 0.218 | 0.15 |
| 6 | 0.24 | 0.141 |
| 7 | 0.366 | 0.22 |
| 8 | 0.278 | 0.168 |
| 9 | 0.471 | 0.36 |
| 10 | 0.351 | 0.243 |

According to the table, by using the PCBs in accordance with the first and second embodiments of the present disclosure, the EMI values of the PCBs are largely decreased. Thus, the edge effects in the signal transmission lines 20 and 50 are also decreased.

Even though numerous characteristics and advantages of the present disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. A printed circuit board (PCB), comprising:
a board body comprising a top surface, a bottom surface, a first side surface, a second side surface, a third side surface and a fourth side surface;
a signal transmission line laid in the board body; and
a metal bracket attached to the board body; wherein the metal bracket comprises a first connecting portion, a second connecting portion, a third connecting portion and a fourth connecting portion which are serially connected; the first connecting portion, the second connecting portion, the third connecting portion and the fourth connecting portion closely contact with the first side surface, the second side surface, the third side surface and the fourth side surface respectively; and the first connecting portion, the second connecting portion, the third connecting portion and the fourth connecting portion are configured to shield electromagnetic interference (EMI) in the signal transmission line when transmitting high-speed differential signals.

2. The PCB of claim 1, wherein the metal bracket further comprises a mounting portion extending from each of an upper edge and a lower edge of each of the first connecting portion, the second connecting portion, the third connecting portion and the fourth connecting portion; and the mounting portions are mounted to the top surface and the bottom surface.

3. The PCB of claim 2, wherein the metal bracket further comprises a mounting hole defined in each of the mounting portions; the board body further comprises a through hole defined in each of four corners of the board body; and the metal bracket is fixed on the board boxy by passing a fastener through each of the through holes and each of the mounting holes.

4. The PCB of claim 3, where the mounting portions are rectangular; and a diameter of each of the through holes is substantially equal to a diameter of each of the mounting holes.

5. The PCB of claim 2, wherein the mounting portions are triangle-shaped; and the mounting portions are riveted to the top surface and the bottom surface.

6. The PCB of claim 1, wherein a length of the first connecting portion and a length of the third connecting portion are substantially equal to a length of the board body; and a length of the second connecting portion and a length of the fourth connecting portion are substantially equal to a width of the board body.

7. The PCB of claim 6, wherein a width of the first connecting portion, the second connecting portion, the third connecting portion and the fourth connecting portion are substantially equal to a thickness of the board body.

8. The PCB of claim 1, wherein the metal bracket is made of copper.

9. The PCB of claim 1, wherein the metal bracket is made of aluminum.

10. A printed circuit board (PCB), comprising:
a board body comprising a plurality of side surfaces;
a signal transmission line laid in the board body adjacent to one of the plurality of side surfaces; and
a metal bracket attached to the board body; wherein the metal bracket closely contact with the plurality of side surfaces of the board body; and the metal bracket is configured to shield electromagnetic interference (EMI) in the signal transmission line when transmitting high-speed differential signals.

11. The PCB of claim 10, wherein the board body further comprises a top surface, a bottom surface, a first side surface, a second side surface, a third side surface and a fourth side surface; the metal bracket comprises a first connecting portion, a second connecting portion, a third connecting portion and a fourth connecting portion which are serially connected; the first connecting portion, the second connecting portion, the third connecting portion and the fourth connecting portion closely contact with the first side surface, the second side surface, the third side surface and the fourth side surface respectively; and the first connecting portion, the second connecting portion, the third connecting portion and the fourth connecting portion are configured to shield EMI in the signal transmission line when transmitting high-speed differential signals.

12. The PCB of claim 11, wherein the metal bracket further comprises a mounting portion extending from each of an upper edge and a lower edge of each of the first connecting portion, the second connecting portion, the third connecting portion and the fourth connecting portion; and the mounting portions are mounted to the top surface and the bottom surface.

13. The PCB of claim 12, wherein the metal bracket further comprises a mounting hole defined in each of the mounting portions; the board body further comprises a through hole defined in each of four corners of the board body; and the metal bracket is fixed on the board boxy by passing a fastener through each of the through holes and each of the mounting holes.

14. The PCB of claim 13, where the mounting portions are rectangular; and a diameter of each of the through holes is substantially equal to a diameter of each of the mounting holes.

15. The PCB of claim 12, wherein the mounting portions are triangle-shaped; and the mounting portions are riveted to the top surface and the bottom surface.

16. The PCB of claim 11, wherein a length of the first connecting portion and a length of the third connecting portion are substantially equal to a length of the board body; and a length of the second connecting portion and a length of the fourth connecting portion are substantially equal to a width of the board body.

17. The PCB of claim 16, wherein a width of the first connecting portion, the second connecting portion, the third connecting portion and the fourth connecting portion are substantially equal to a thickness of the board body.

18. The PCB of claim 10, wherein the metal bracket is made of copper.

19. The PCB of claim 10, wherein the metal bracket is made of copper.
